(19) United States
(12) Patent Application Publication
(10) Pub. No.: US 2006/0187700 A1
(43) Pub. Date: Aug. 24, 2006

(54) Single event effect (SEE) tolerant circuit design strategy for SOI type technology

(75) Inventor: Iu-Meng Tom Ho, Milpitas, CA (US)

Correspondence Address: PATTON BOGGS, 1660 LINCOLN ST, SUITE 2050, DENVER, CO, 80264, US

(73) Assignee: Iota Technology, Inc., San Jose, CA (US)

(21) Appl. No.: 11/350,673

(22) Filed: Feb. 8, 2006

Related U.S. Application Data
(60) Provisional application No. 60/650,787, filed on Feb. 8, 2005.

(51) Int. Cl. G11C 11/22

(52) U.S. Cl. 365/145

(57) ABSTRACT

A method of designing an integrated circuit to be Single Event Upset (SEU) immune by converting one or more Single Event Transient (SET) sensitive transistors into at least two serially connected transistors, and spacing the transistors sufficiently far apart so that the probability of a specified high-energy particle striking both transistors at the same time is remote.

### CROSS-REFERENCE TO RELATED APPLICATIONS

This Application is a Non-Provisional Application of Provisional (35 USC 119(e)) Application No. 60/650,787 filed on Feb. 8, 2005 and claims the benefit thereof.

### FIELD OF THE INVENTION

The invention relates to the field of integrated circuits, and more particularly, but not by way of limitation, to silicon-on-insulator (SOI) technology.

### BACKGROUND OF THE INVENTION

As indicated in FIG. 1, when a high-energy subatomic particle 12 strikes an integrated circuit with PN junctions, whole-electron pairs are produced. The state or drive characteristic of the circuit node connected to the struck PN junction can be altered or affected. For technologies like the SOI, SOA (Silicon-On-Anything), SOS, Bulk on Epi, or Bulk with buried oxide, where Single Event Effect (SEE) can trigger the bipolar back-channel to turn on, an originally “OFF” transistor can be turned “ON” momentarily by the high-energy particle. For a driven node, the effect comes as a glitch if the strength of the driving transistor is not strong enough to overcome the momentarily turned “ON” of bipolar back channel. This is called a Single Event Transient (SET). If the SET is allowed to propagate to a storage node and be latched, the original stored data is destroyed, which is called a Single Event Upset (SEU). Most Single Event Effect (SEE) problems for Silicon On Insulator (SOI) type CMOS integrated circuits are caused by the momentarily forward biasing of the back-channel bipolar transistor of an OFF transistor.

It is a common practice for Bulk CMOS circuit designers to raise supply voltages and/or increase capacitive loading or RC loading on the SEE sensitive nodes to minimize the effect of Single Event Transient (SET) to cause a Single Event Upset (SEU). The following patents use capacitors and/or resistors to increase the resistivity of SRAM cells to Single Event Upset (SEU): U.S. Pat. No. 5,917,212 issued Jun. 29, 1999 to Blake et al.; U.S. Pat. No. 5,204,990 issued Apr. 20, 1993 to Blake et al.; U.S. Pat. No. 4,725,981 issued Feb. 16, 1988 to Rutledge; U.S. Pat. No. 4,833,644 issued May 23, 1989 to Plus et al.; U.S. Pat. No. 4,912,675 issued Mar. 27, 1990 to Blake et al., and U.S. Pat. No. 4,956,814 issued Sep. 11, 1990 to Houston.

With the availability of SOI CMOS, circuit designers are still using the same techniques developed for bulk CMOS. Even for current SOI CMOS SRAMs, circuit designers are using RC delays to slow down the effect of SET on the two latched storage nodes. This can provide SEE tolerant of up to LET=164 MeV/(mg/cm²). See K. Hirose, H. Saito, Y. Kuroda, S. Ishii, Y. Fukuoka, and D. Takahashi, “SEU Resistance in Advanced SOI-SRAMs Fabricated by Commercial Technology Using a RAD-Hard Circuit Design”, IEEE Transactions on Nuclear Science, Vol. 49, No. 6, December 2002.

Increasing power supply voltage is an effective way to reduce the effect of SET to cause a Single Event Upset (SEU). Circuit designers generally use 3.3 v or higher power supply to have better SEU resistivity. However, most very deep submicron SOI CMOS can only handle a power supply at 1.8 v or lower. Thus, using a high power supply can greatly limit the choices of very advanced technologies.

A large area penalty is required to provide enough capacitance and resistance in a conventional integrated circuit to improve the SEU resistivity. Further, the additional RC delays impact the performance of the specific circuit directly. In addition, it is time consuming for circuit and layout designers to come up with enough capacitance without costing too much silicon area to suppress glitches coming from SET for a regular CMOS or CMOS SOI process.

Thus, there is a need for a simple, easily applied method and apparatus for reducing the effect of SET and SEU in integrated circuits, particularly SOI integrated circuits, which does not rely on adding capacitance or raising power supply voltages.

### BRIEF SUMMARY OF THE INVENTION

The invention provides a solution to the above and other problems by replacing each of the Single Event Effect (SEE) susceptible transistors with a plurality of serially connected gates to ensure undisturbed output levels free of unwanted glitches or Single Event Transient (SET) and Single Event Upset (SEU).

As shown in FIG. 1, a redundant transistor 10 is added (can be multiple) so that when one of the transistors gets hit by an energetic subatomic particle, the transistor replacement will remain in the “OFF” state, or the whole circuit will remain in the same logic state. This approach works for all the transistor types, i.e. NMOS, PMOS, DMOS, etc., available in the technology being used.

The invention provides a method of designing an integrated circuit to be Single Event Upset (SEU) immune, the integrated circuit having one or more Single Event Transient (SET) sensitive transistors, the method comprising: converting one or more of the one or more Single Event Transient (SET) sensitive transistors into at least two serially connected transistors; and spacing the at least two transistors sufficiently far apart that the probability of a specified high-energy particle striking both transistors at the same time is remote. Preferably, the at least two serially connected transistors are spaced apart by inserting or serially connected transistors on the same branch of the circuit. Preferably, the integrated circuit is an SOI/SOS type integrated circuit. Preferably, the at least two serially connected transistors are of the same transistor type. Preferably, the integrated circuit comprises an inverter or driver, a two input NAND gate, a DRAM cell, an SRAM cell, a latch, an FeRAM cell, a 1T1C FeRAM cell, a 3T2C Trinion FeRAM cell, or a dynamic charge storage 1-write-1-read (1W1R) register cell. Preferably, the integrated circuit comprises NMOS or PMOS passgate transistors. Preferably, the probability is one in a million or less. More preferably, the probability is one in a billion or less. Most preferably, the probability is one in a trillion or less.

The invention also provides a method of manufacturing a Single Event Upset (SEU) immune integrated circuit, the method comprising: providing a design for an integrated circuit, the integrated circuit comprising a Single Event Transient (SET) sensitive transistor, and inserting a serially connected transistor pair for the SET transistor, wherein the transistors in the transistor pair are separated by a distance such that the probability of a high-energy particle of a predetermined energy striking both transistors at the same time is remote. Preferably, the probability is one in 10⁶ or less. Preferably, said spacing is greater than 0.1 micron. Most preferably, said spacing is 0.3 microns or more, and most preferably 0.5 microns or more.

The invention offers a quick way to suppress SET and SEU glitches without costing significant design time, capacitance, or silicon area. This and other advantages will be understood more fully when the detailed description below is read in conjunction with the following drawings.

### BRIEF DESCRIPTION OF THE DRAWINGS

FIG. 1 is an illustration of the basic concept of the invention;

FIG. 2 illustrates the application of the invention of FIG. 1 to an inverter;

FIG. 3 illustrates the application of the invention of FIG. 1 to a two input NAND gate;

FIGS. 4A and 4B illustrate the application of the invention of FIG. 1 to various pass gates and transistors;

FIG. 5 illustrates variations on the invention of FIGS. 4A and 4B;

FIG. 6 illustrates the application of the invention of FIG. 1 to a DRAM cell;

FIG. 7 is a further illustration of the application of the invention of FIG. 1 to a DRAM cell;

FIG. 8 illustrates the application of the invention of FIG. 1 to an SRAM cell;

FIG. 9 illustrates a variation on the application of the invention of FIG. 1 to an SRAM cell;

FIG. 10 illustrates the application of the invention of FIG. 1 to a 1T1C FeRAM cell;

FIG. 11 illustrates another application of the invention of FIG. 1 to a 1T1C FeRAM cell;

FIG. 12 illustrates the application of the invention of FIG. 1 to a 3T2C Trinion FeRAM cell;

FIG. 13 illustrates another application of the invention of FIG. 1 to a 3T2C Trinion FeRAM cell;

FIG. 14 illustrates a further application of the invention of FIG. 1 to a 3T2C Trinion FeRAM cell;

FIG. 15 illustrates another application of the invention of FIG. 1 to a 3T2C Trinion FeRAM cell;

FIG. 16 illustrates a further application of the invention of FIG. 1 to a 3T2C Trinion FeRAM cell;

FIG. 17 illustrates the application of the invention of FIG. 1 to a dynamic charge storage 1-write-1-read (1W1R) register cell; and

FIG. 18 illustrates another application of the invention of FIG. 1 to a dynamic charge storage 1-write-1-read (1W1R) register cell.

### DETAILED DESCRIPTION OF THE INVENTION

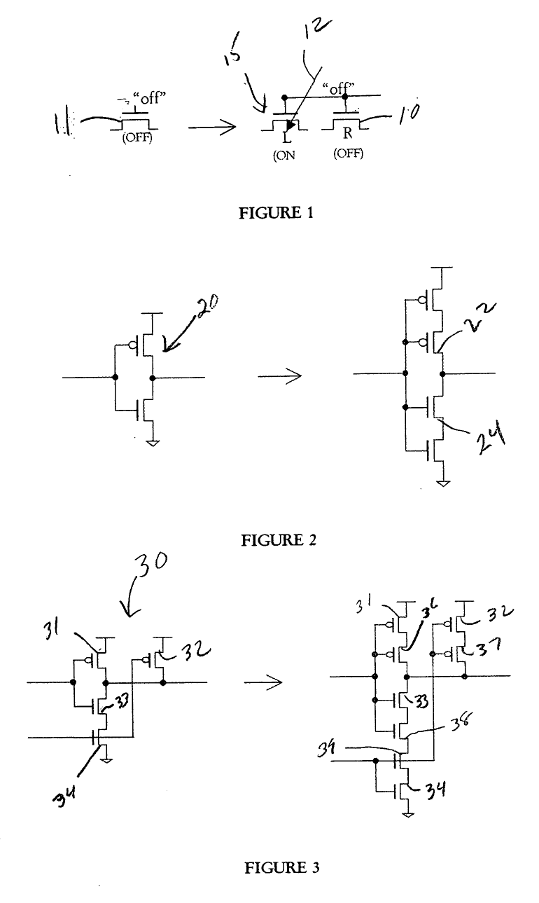

As indicated in FIG. 1, when a high-energy subatomic particle 12 strikes an integrated circuit with PN junctions, whole-electron pairs are produced. The state or drive characteristic of the circuit node connected to the struck PN junction can be altered or affected. For technologies like the SOI, SOA (Silicon-On-Anything), SOS, Bulk on Epi, or Bulk with buried oxide, where SEE can trigger the bipolar back-channel to turn on, an originally “OFF” transistor can be turned “ON” momentarily by the high-energy particle. For a driven node, the effect comes as a glitch if the strength of the driving transistor is not strong enough to overcome the momentarily turned “ON” of the bipolar back channel. This is called a Single Event Transient (SET). If the SET is allowed to propagate to a storage node and be latched, the original stored data is destroyed, which is called a Single Event Upset (SEU). The driving node can be an output of an inverter, buffer, passgate, NMOS, PMOS, tri-state drivers, any logic gates, or any combinations of driving schemes. For a capacitive node with stored charge like a DRAM cell, the high-energy particle will alter the charge stored, thus destroying the original data stored in the Dynamic Storage Memory.

A SET glitch-free circuit can be obtained when all the “OFF” transistors remain “OFF” when being bombarded by high-energy subatomic particles. This can be done by replacing all the SEE sensitive transistors, such as 11, with the serially connected transistor pairs 15. The serially connected pair can be connected together like a dual serially connected transistor pair with a spacing wide enough so that when one transistor gets hit by a high-energy subatomic particle, the other will still be in the “OFF” state. The spacing is dependent on the technology used, the energy level of the particle, and the specified size of the particle. To provide enough distance between the serially connected pair while using minimum transistor spacing design rules, the serially connected pair can be separated by other pairs in logic gates implementations to provide enough distance between the pair while at the same time using minimum spacing design rules for area efficiency. The distance the two transistors in each serially connected transistor pair are apart will depend on the specification of the customer for the energy of the particles to which the device will be exposed. The higher the energy of the particles, the farther apart the transistors should be. Preferably, the transistors in the serially connected pair are sufficiently far apart that the probability of a single particle striking both transistors is negligible, preferably, less than one in 10⁶. Generally, on Earth, a subatomic particle has an energy footprint of about 0.1 micron. Thus, if the serially connected pair is 0.5 microns apart, which is easily possible for integrated circuits made as disclosed herein with state-of-the-art integrated circuit technology, the chance of a single particle hitting both will be too small to measure. As technology advances, this will be harder to do, but preferably the integrated circuit should be laid out so that the spacing is preferably 0.3 microns or more apart, and more preferably 0.4 microns or more apart.

FIG. 2 shows a conventional inverter 20 modified by adding additional transistors 22 and 24 to be SEE glitch free.

FIG. 3 is an example of how two input NAND gates 30 can be modified to be SEE glitch free with the present invention. Each transistor 31, 32, 33, and 34 is modified by adding a serially connected transistor 36, 37, 38, and 39, respectively. Other logic gates can also be converted with the same methodology.

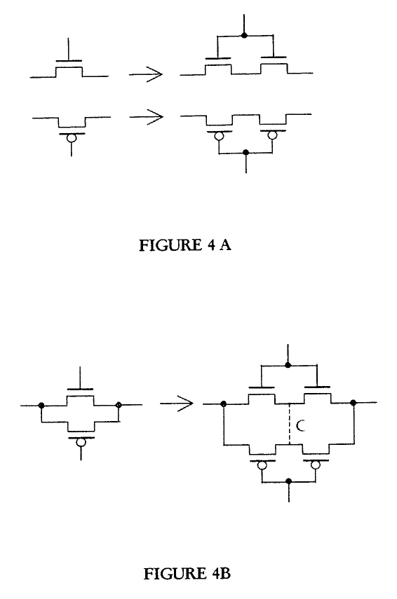

FIGS. 4A and 4B are examples of how different versions of passgates and transistors can be converted to SEE immune passgates or serially connected transistors. The connection “C” is optional.

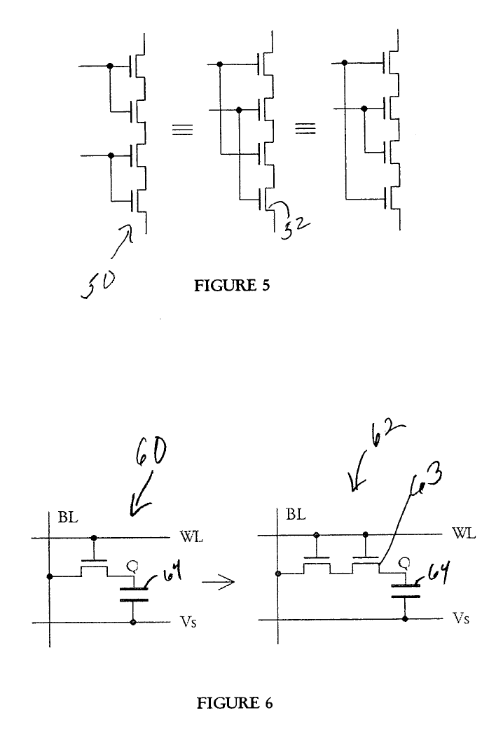

FIG. 5 is an example of how the serially connected gates 50 can be implemented with different variations. The NMOS transistors, such as 52, in this charge storage device can be PMOS or any available transistor types in the specific technology.

FIG. 6 shows how conventional DRAM cell 60 can be modified to form a SEE immune charge storage node 62, or a DRAM cell by adding an additional transistor 63. The NMOS passgate in this charge storage device can be a PMOS or Complimentary NMOS/PMOS transmission gate. The charge storage capacitor 64 can be any capacitor implemented with the specific technology and any transistor used as charge storage. Any storage cells or registers with dynamic storage nodes can also be converted the same way.

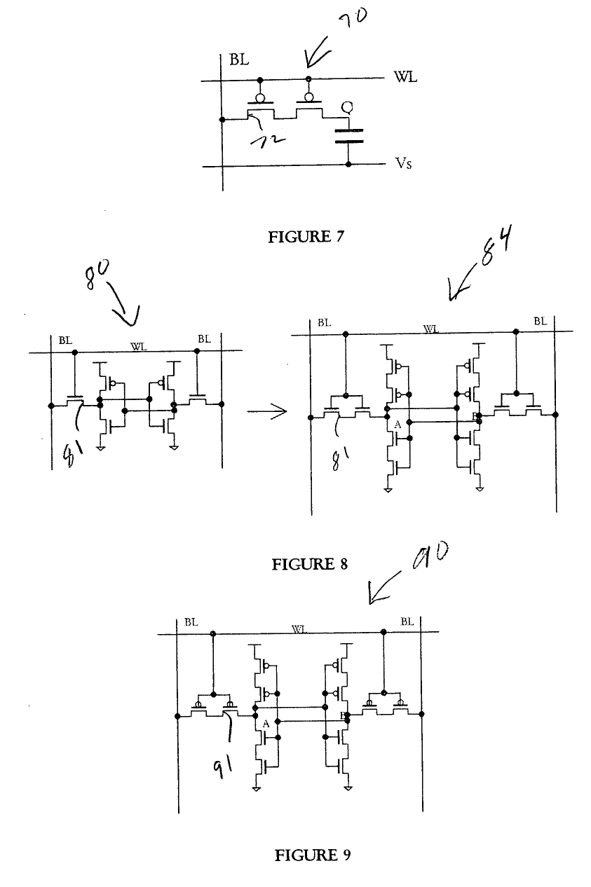

FIG. 7 shows how a high TID tolerant SEE immune charge storage node or a DRAM cell 70 can be implemented with PMOS transistors, such as 72.

FIG. 8 shows how a conventional SRAM cell or a cross-couple latch 80 can be implemented to form an SEU immune SRAM cell 84. The NMOS passgate 81 on both cells can be a PMOS or a Complimentary NMOS/PMOS transmission gate. A small capacitance can be added to the latched nodes “A” and “B” to further increase the SEU resistivity. Any latches or flip-flops can be converted the same way.

FIG. 9 shows how a high TID tolerant SEE immune SRAM cell or a cross-couple latch 90 can be implemented with PMOS pass transistors, such as 91. A small capacitance can be added to the latched nodes “A” and “B” to further increase the SEU resistivity.

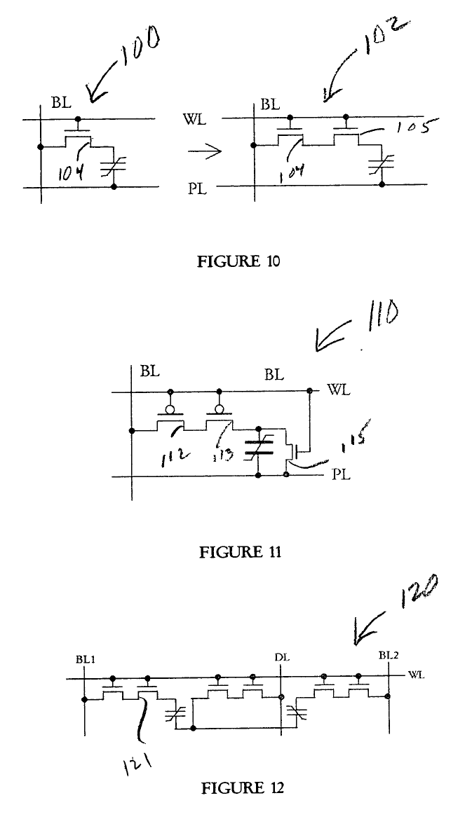

FIG. 10 shows how a 1T1C FeRAM cell 100 can be converted to an SEU immune basic 1T1C FeRAM cell 102. The NMOS passgates 104, 105 on both cells can be PMOS.

FIG. 11 shows how a high TID tolerant SEE immune 1T1C FeRAM cell can be implemented with PMOS pass transistors 112 and 113 and a NMOS transistor 115 for shorting the ferroelectric capacitor when the cell is not selected.

FIG. 12 shows how an SEU immune basic 3T2C Trinion FeRAM cell 120 can be implemented. See U.S. Pat. No. 6,809,949 B2 issued Oct. 26, 2004 to Iu-Meng Tom Ho, which is hereby incorporated by reference to the same extent as though fully disclosed herein. The NMOS passgates, such as 121, can be PMOS.

FIG. 13 shows how a high TID tolerant SEE immune Trinion FeRAM cell 130 can be implemented with PMOS as pass transistors, such as 132, and NMOS transistors A and B for shorting the ferroelectric capacitors when the cell is not selected.

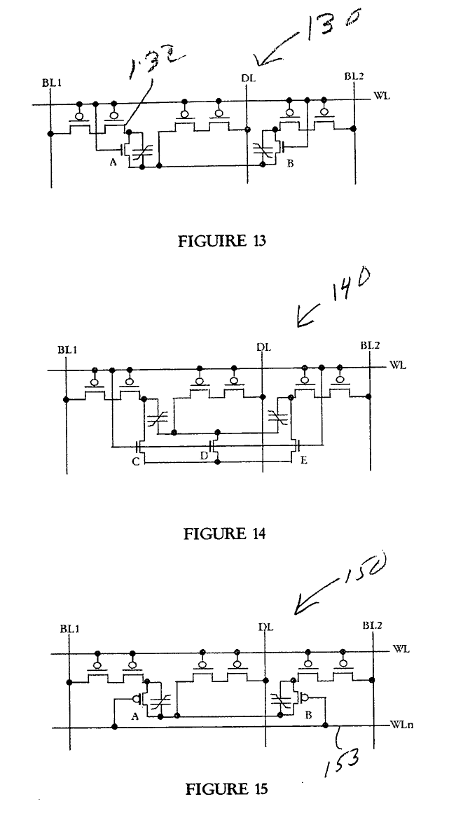

FIG. 14 is a possible variation 140 of the circuit in FIG. 13 for layout efficiency, with shorting transistors C, D, and E.

FIG. 15 shows another variation 150 of the circuit in FIG. 13 when the two NMOS shorting transistors A and B are implemented in a PMOS driven by signal WLn on complimentary word line 153. WLn is the complimentary signal of WL.

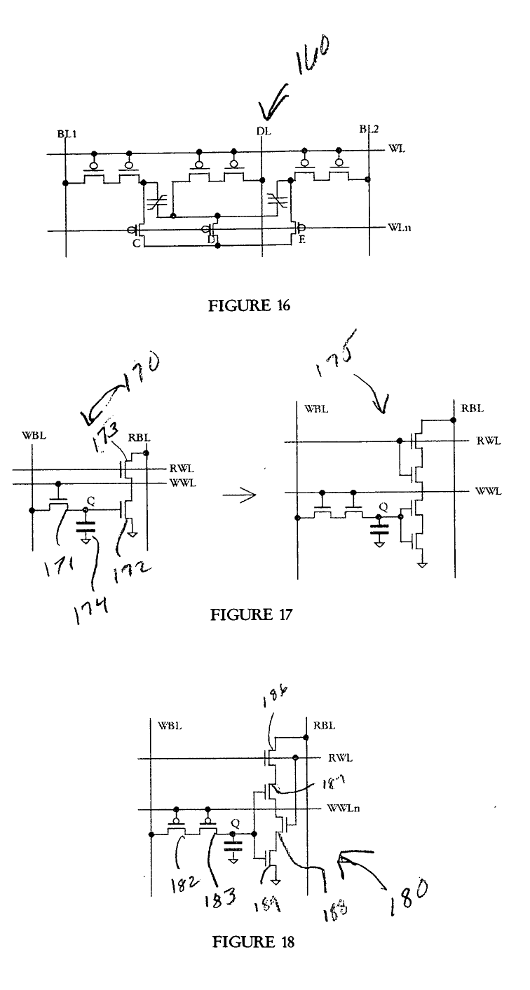

FIG. 16 is a possible variation 160 of the circuit in FIG. 15 for layout efficiency, with shorting transistors C, D, and E.

FIG. 17 shows how a conventional dynamic charge storage 1-write-1-read (1W1R) register cell 170 and be modified to an SEE immune dynamic charge storage 1-write-1-read (1W1R) register cell 175. The NMOS passgates 171, 172, and 173 in this charge storage device can be a PMOS or a Complimentary NMOS/PMOS transmission gate. The charge storage capacitor 174 can be any capacitor implemented with the specific technology or any transistor used as charge storage.

FIG. 18 shows how a high TID tolerant SEE immune dynamic charge storage 1-write-1-read (1W1R) register cell 180 can be implemented with PMOS transistors 182 and 183, and the NMOS serial pulldown transistors 186, 187, 188, and 189 are rearranged to get better SEE tolerance.

All of the SOI CMOS transistors as described in the above circuits have the body connections intentionally left out for simplicity. It is up to the circuit designers to decide if an individual transistor should have a floating body, a body-tie with certain voltage, source-tie, etc. The chip substrate or back-gate voltage is also left out. It is also up to the circuit designers to decide whether to have a floating substrate, grounded substrate, connected to a certain supply, etc.

An advantage of this invention is that it can effectively be used with the most advanced SOI/SOS type technologies, such as a very deep submicron SOI CMOS which can only handle power supplies at 1.8 v or lower.

There has been described a circuit design methodology using multiple serially connected transistors to improve SEE tolerant of an integrated circuit fabricated with SOI type technologies. Now that various circuits using this methodology have been described, those skilled in the electronics arts may make many variations. It should be understood that the particular embodiments shown in the drawings and described within this specification are for purposes of example and should not be construed to limit the invention, which will be described in the claims below. Further, it is evident that those skilled in the art may now make numerous uses and modifications of the specific embodiments described without departing from the inventive concepts. It is also evident that the methods recited may, in many instances, be performed in a different order, or equivalent components may be used in the memories and logic gates, and/or equivalent processes may be substituted for the various processes described. Consequently, the invention is to be construed as embracing each and every novel feature and novel combination of features present in and/or possessed by the invention herein described.

What is claimed as new and desired to be protected by Letters Patent of the United States is:

1. A method of designing an integrated circuit to be Single Event Upset (SEU) immune, said integrated circuit having one or more Single Event Transient (SET) sensitive transistors, said method comprising:
converting one or more of said one or more Single Event Transient (SET) sensitive transistors into at least two serially connected transistors; and
spacing said at least two transistors sufficiently far apart so that the probability of a specified high-energy particle striking both transistors at the same time is remote.

2. A method as in claim 1 wherein said at least two serially connected transistors are spaced apart by inserting other serially connected transistors on the same branch of said circuit.

3. A method as in claim 1 wherein said integrated circuit is an SOI/SOS type integrated circuit.

4. A method as in claim 1 wherein said at least two serially connected transistors are of the same transistor type.

5. A method as described in claim 1 wherein said integrated circuit comprises an inverter or driver.

6. A method as described in claim 1 wherein said integrated circuit comprises a two input NAND gate.

7. A method as described in claim 1 wherein said integrated circuit comprises a DRAM cell.

8. A method as described in claim 1 wherein said integrated circuit comprises an SRAM cell.

9. A method as described in claim 1 wherein said integrated circuit comprises a latch.

10. A method as described in claim 1 wherein said integrated circuit comprises an FeRAM cell.

11. A method as described in claim 10 wherein said integrated circuit comprises a 1T1C FeRAM cell.

12. A method as described in claim 1 wherein said integrated circuit comprises a 3T2C Trinion FeRAM cell.

13. A method as described in claim 1 wherein said integrated circuit comprises a dynamic charge storage 1-write-1-read (1W1R) register cell.

14. A method as described in claim 1 wherein said integrated circuit comprises NMOS or PMOS passgate transistors.

15. A method as in claim 1 wherein said probability is one in 10⁶ or less.

16. A method of manufacturing a Single Event Upset (SEU) immune integrated circuit, said method comprising:
providing a design for an integrated circuit, said integrated circuit comprising a Single Event Transient (SET) sensitive transistor; and
inserting a serially connected transistor pair for said SET transistor, wherein the transistors in said transistor pair are separated by a distance such that the probability of a high-energy particle of a predetermined energy striking both transistors at the same time is remote.

17. A method as in claim 16 wherein said probability is one in 10⁶ or less.

18. A method as in claim 16 wherein said spacing is 0.1 micron or more.

19. A method as in claim 16 wherein said spacing is 0.5 microns or more
